(19) United States
(12) Patent Application Publication
(10) Pub. No.: US 2026/0358424 A1
(43) Pub. Date: Nov. 12, 2026

(54) Predicting the Service Life of a High-Voltage Storage Device for a v2x Operation

(71) Applicant: Bayerische Motoren Werke Aktiengesellschaft, Muenchen (DE)

(72) Inventor: Jens BERGER, Muenchen (DE)

(21) Appl. No.: 19/515,675

(22) PCT Filed: Sep. 19, 2024
(86) PCT No.: PCT/DE2024/100826

§ 371 Date: Mar. 2, 2026

(30) Foreign Application Priority Data
Sep. 19, 2023 (DE) 10 2023 125 364.6

(51) Int. Cl. G01R 31/367; B60L 53/62; B60L 53/66; B60L 55/00; G01R 31/392

(52) U.S. Cl. CPC G01R 31/367; B60L 53/62; B60L 53/66; B60L 55/00; G01R 31/392

(57) ABSTRACT

The present disclosure relates to a method for predicting at least a remaining service life of at least one component of a high-voltage storage system, which is installed in an electric vehicle designed for bidirectional charging, for V2X operation, wherein the at least one component of the high-voltage storage system is categorized into at least one respective category of a group of component usage categories using the usage behavior of the component, a category-specific model for the component is selected using the categorization, at least one corresponding remaining service life variable is predicted using the usage behavior and the selected model of the at least one component, and at least a remaining service life for the V2X operation of the at least one component is determined using the at least one predicted remaining service life variable.

### BACKGROUND AND SUMMARY

The invention relates to a method for predicting a residual service life of at least one component of a high-voltage storage system which is installed in an electric vehicle which is designed for bidirectional charging, for V2X operation. The invention also relates to a prediction system comprising at least one electric vehicle and a data processing entity, wherein the prediction system is designed to execute the method. The invention is particularly advantageously applicable to fully electrically powered electric vehicles.

It is known for high-voltage storage devices of electric vehicles connected to charging points, such as drive batteries, to be employed as buffer storage devices, and thus to be bidirectionally charged, i.e. optionally charged or discharged. Typical applications to this effect include V2H (“vehicle-to-home”) and V2G (“vehicle-to-grid”) applications. Economic and/or ecological benefits of these applications are offset by the disadvantage to the effect that, as a result, the high-voltage storage device undergoes additional loading, as a result of which the state-of-health (SoH) and/or the residual service life thereof declines more rapidly than in the event of driving operation only. The same applies, in an analogous manner, to vehicle components such as battery electronics, etc., and also to charging points which are likewise operated in-service as buffer storage devices.

It is moreover known, in the event of an overshoot of a specific number of hours of service in a reinjection mode, or in the event of an overshoot of a specific quantity of reinjected energy from the high-voltage storage device, for the discharging function, and thus the bidirectional charging function, to be interrupted on the vehicle side, c.f. for example Sepp Reitberger: “E-Auto von VW kann nun Strom in Netz speisen: Doch die Technik stöβt an Grenzen” [VW electric cars can now feed power into the grid: however, the technology is reaching its limits], EFAHRER.com of 14.07.2022. The hours of service of the high-voltage storage device in a driving mode and in a charging mode can be ascertained, for example, by means of a service hour counter in the electric vehicle. It is moreover known, in the event of an overshoot of a fixedly predefined energy throughput and/or of a specific limiting temperature of the high-voltage storage device, for the discharging function to be limited, or even interrupted, on the vehicle side.

Design ratings for the above-mentioned limitations of the high-voltage storage device during discharging are determined by reference to predefined temperature, loading and storage level profiles and, for other components of an electric vehicle, typically by reference to a preliminarily assumed mileage and a preliminarily assumed number of hours of service. Only during the service phase of the actual electric vehicle will it become evident whether the above-mentioned assumptions have been appropriately selected: thus, under certain circumstances, bidirectional charging is inhibited, even though the high-voltage storage device and associated further components are still in a “sound” condition, or the discharging function would still be employable with a reduced capacity. If components are unable to withstand the design rating, this can result in unwanted outages.

It is known for the state-of-health of a high-voltage storage device to be ascertained from historic vehicle data, such as the number and/or duration of charging cycles and the energy throughput or, alternatively, to be ascertained by measurement.

FR 3044424 A1 discloses a portable diagnostic device for a traction battery of the lithium-ion type on board an electric vehicle or a rechargeable hybrid vehicle, which device comprises: means for measuring a voltage, a current and a temperature of the battery; a control unit for supplying a diagnosis; an electronics box, which comprises a switch which is controlled by the control unit for the application of a load profile which is ascertained for the purposes of diagnosis, and which can be directly connected to an external charging terminal and to the charging device of the on-board battery. During the servicing of the vehicle, a diagnosis can be executed independently of the battery management system, or BMS, without the necessity for the removal of the battery, in order to determine the state-of-health of the battery and the residual service life thereof.

DE 10 2017 200 996 A1 discloses a method for determining a state-of-health of an energy storage device of an electric vehicle, which method comprises the following steps: provision of a test routine, which provides for an active load test of the energy storage device of the electric vehicle, wherein at least one energy storage device component of the energy storage device of the electric vehicle is energized with a charging current and/or a discharging current, wherein the test routine gauges at least one state-of-health-dependent parameter of the energy storage device; activation of the test routine in response to an operating signal and/or a time generator signal, which signal is external to the energy storage device; verification as to whether the electric vehicle is connected to a charging column, and execution of the test routine in the connected state: ascertainment of the state-of-health of the energy storage device from the at least one state-of-health-dependent parameter of the energy storage device, and transmission of the state-of-health of the energy storage device thus ascertained to a receiver which is external to the energy storage device. An electric vehicle is moreover disclosed, having means for executing the method for the determination of the state-of-health of an energy storage device.

DE 10 2019 205 843 A1 discloses a method for evaluating the state-of-health of a high-voltage battery of a hybrid vehicle in the installed state, which method comprises the following steps: set-up of a connection between a test unit and a battery control device; verification of compliance with stipulated test conditions; execution of a static test sequence, wherein at least one static battery characteristic is ascertained; execution of a dynamic test sequence, wherein at least one dynamic battery characteristic is ascertained; calculation of the overall state-of-health of the high-voltage battery from the at least one static battery characteristic and the at least one dynamic battery characteristic.

M.S. Hossain Lipu et al: “A review of state of health and remaining useful life estimation methods for lithium-ion battery in electric vehicles: Challenges and recommendations”, Journal of Cleaner Production, September 2018, provides an overview of various methods for determining the state-of-health of a battery, including Coulomb counting.

An object of the present invention is to at least partially surmount the disadvantages of the prior art and, in particular, to provide an improved option for the determination, and optionally for the extension, of a residual service life of at least one component of a high-voltage storage system of an electric vehicle which is designed for bidirectional charging, for employment in V2X operation.

This object is addressed according to the features of the independent claims. In particular, preferred embodiments can be inferred from the dependent claims.

The object is addressed by a method for predicting at least one residual service life of at least one component of a high-voltage storage system which is installed in an electric vehicle which is designed for bidirectional charging, for V2X operation, wherein:
the at least one component of the high-voltage storage device, by reference to the usage behavior thereof, is categorized in at least one respective category of a group of component usage categories;
by reference to the categorization, a category-specific model for this component is selected;
by reference to the usage behavior and to the selected model of the at least one component, at least one associated residual service life variable is predicted; and
by reference to the at least one predicted residual service life variable, at least one residual service life for the V2X operation of the at least one component is determined.

This method provides an advantage in that, in a reliable manner, an accurate determination of the residual service life of the at least one component for V2X operation (also referred to hereinafter as the “V2X residual service life”) is enabled in the normal operation of the electric vehicle. Advantageously, stringent constraints upon V2X operation associated with preliminarily determined variables, or variables which are not relevant to the current electric vehicle, such as a number of hours of service of the high-voltage storage device in a reinjection mode, or a reinjected quantity of energy, can thus be omitted. For example, in the event of the conservative utilization of the high-voltage storage device, an increased service life can be achieved, in comparison with a stipulated starting value. On the other hand, in the event of a non-conservative or heavy-duty utilization of the high-voltage storage device, the service life can even be reduced in comparison with the starting value, wherein it can thus be advantageously prevented that the high-voltage storage device is excessively loaded by V2X operation.

In particular, V2X (“vehicle-to-everything”) operation is understood as the facility for the injection of electrical energy from the high-voltage storage device into an off-vehicle power grid “X” and, in particular, for the employment thereof as a buffer storage device. V2X operation can comprise, for example, a V2H (“vehicle-to-home”), a V2G (“vehicle-to-grid”), a V2B (“vehicle-to-business”) operation, etc.

In particular, the residual service life for V2X operation corresponds to the remaining service life of the relevant component, until such time as the employment thereof for V2X operation will be foreseeably restricted and/or inhibited.

The electric vehicle is, for example, a plug-in hybrid vehicle, or PHEV, or a fully electrically powered vehicle, e.g. a battery electric vehicle, or BEV. The electric vehicle can be a passenger car, a heavy goods vehicle, a bus, a motorcycle, etc. The fact that the electric vehicle is designed for bidirectional charging signifies in particular that the vehicle is designed or configured for the high-voltage storage device thereof to be optionally recharged or discharged. Within this meaning, in the present context, the term “charging” can be understood to signify both “recharging” and “discharging”, and a charging process can thus analogously correspond to a recharging process and/or to a discharging process.

The electric vehicle comprises an on-board high-voltage storage system, which comprises at least one high-voltage storage device, e.g. one or more high-voltage storage devices. The high-voltage storage device can be an accumulator, in particular a battery, specifically a lithium-ion battery. The high-voltage storage device can be a drive battery or traction battery of the electric vehicle. The high-voltage storage device can be employed in the electric vehicle at a voltage of for example 60 V or higher, e.g. at 60 V, 120 V, 400 V, 800 V or higher. In particular, the high-voltage storage device is connected to an on-board power supply system of the electric vehicle, which system assumes a corresponding on-board system voltage. The high-voltage storage system can moreover comprise at least one further component, which is employed for operating the at least one high-voltage storage device, e.g. at least one electronic component (also referred to hereinafter, without loss of generality, as “battery electronics”).

In particular, categorization of the at least one component, by reference to the usage behavior thereof (in particular how and/or under what conditions the component is used), in one usage category of a group of usage categories (“component usage categories”) signifies that at least one component parameter which corresponds to the respective category is determined, e.g. is measured, estimated or inferred, which parameter is appropriate for the characterization of usage behavior, and a respective categorization is executed for this at least one component parameter. In particular, determination of a component parameter can signify that a value thereof is determined, a cumulative value is determined, or a temporal value progression is ascertained. In particular, a usage category comprises at least two different and disjunctive regions (“classes”) to which the content/value of the associated component parameter is or can be unequivocally assigned. The group of component usage categories can thus comprise one or more component usage categories, each of which is subdivided into at least two classes for a respective corresponding component parameter. Categorization can also be considered or designated as classification, and categorizing as classifying.

The classes can be value ranges or similarity ranges. In the case of value ranges, for example, the value of the associated component parameter thus ascertained falls within one of the classes. In the case of similarity ranges, for example, a value progression of the associated component parameter thus ascertained falls within that class the reference curve of which assumes the highest degree of similarity to the value progression thus ascertained. As a measure of similarity or deviation, for example, the sum of squared errors can be employed. The classes can then correspond to different value ranges of the measure of similarity.

By reference to this categorization or classification, a most appropriate (category-specific) model of the component is selected. In particular, a specific model can be assigned to each class or combination of classes, which model most effectively describes this class or combination of classes. The model is, for example, a physico-chemical model. The selection can be executed automatically, e.g. by means of an algorithm.

In particular, prediction of at least one associated residual service life variable by reference to the usage behavior (at least represented by the values of the component parameter) and by reference to the selected category-specific model of the at least one component signifies that, from the selected model of the component, by means of actual data for the relevant electric vehicle, the at least one future residual service life variable is calculated, wherein, for the purposes of prediction, in particular, a consistent usage behavior is assumed. In particular, these actual data include the measured values for the component parameter in the electric vehicle considered, or progressions thereof, but are not limited thereto.

In particular, determination of the remaining V2X residual service life by reference to the at least one predicted residual service life variable signifies that the at least one residual service life variable represents a measure of the V2X residual service life. Consequently, from the at least one residual service life variable, the at least one V2X residual service life can be inferred. As the at least one residual service life variable is related to the at least one V2X residual service life, determination thereof, for example by a manufacturer, is thus enabled. By reference to the at least one predicted residual service life variable, according to a further development, the remaining service life of the component can be determined. According to a further development, the remaining service life of the component can be employed as an input variable for determining the V2X residual service life.

According to one configuration, the at least one component comprises at least one high-voltage storage device and, in particular, is at least one high-voltage storage device. Hereinafter, the associated component usage categories, without loss of generality, are designated as battery usage categories. In particular, the at least one battery usage category employed for predicting the residual service life variable comprises at least two battery usage categories. The at least two battery usage categories comprise at least two categories from the following group:
energy throughput per unit of time at a charging point;
number of charging cycles per unit of time or per charging process at a charging point;
energy throughput per unit of time during a driving operation;
total energy throughput;
temperature of the high-voltage storage device, in particular per unit of time;
storage level of the high-voltage storage device, in particular per unit of time.

Each of these battery usage categories significantly influences both the residual service life of the high-voltage storage device up to the end-of-life thereof (can also be referred to as the “remaining service life”) and the V2X residual service life of the high-voltage storage device.

The energy throughput per unit of time at a charging point can exemplarily comprise a charging capacity, a temporal characteristic of charging capacity and/or at least one variable inferred therefrom, for example a mean value of a charging capacity per charging process, and a maximum value of charging capacity per charging process, etc. Potential classes can include, for example, one class having a low charging capacity and one class having a high charging capacity. The class having a low charging capacity can be associated, for example, with “normal charging” (e.g. charging at a charging capacity of no more than 11 kW), which is more protective of the battery than “fast charging” at a high charging capacity. According to a further development, the energy throughput per unit of time at a charging point can comprise a corresponding characteristic or a corresponding profile and, for example, can be classified in classes which are defined by respective reference characteristics, e.g. by means of a similarity comparison. The charging point can be, for example, a charging station, such as a commercial charging column or a wallbox, or can be an inductive charging point.

The number of charging cycles also influences the residual service life: the higher this number, the more rapid the potential ageing of the high-voltage storage device. The classes can correspond e.g. to respective value ranges.

The energy throughput per unit of time during a driving operation can include a discharging associated with an operation of a drive motor and, optionally, also a recharging associated with a regenerative operation. Here again, the energy throughput per unit of time can exemplarily comprises a charging capacity, a temporal characteristic of charging capacity and/or at least one variable inferred therefrom, for example a mean value of a charging capacity during driving operation, etc. In the event that, for example, the category considered corresponds to the mean value, potential classes can exemplarily comprise one class having a low averaged charging capacity and one class having a high averaged charging capacity. The class having a low averaged charging capacity can be associated, for example, with “slow driving”, which is more protective of the battery than “fast driving” with a high averaged charging capacity. According to a further development, it is also possible e.g. that the energy throughput per unit of time comprises a corresponding characteristic or a corresponding profile and, for example, is classified in classes which are defined by respective reference characteristics, e.g. by means of a similarity comparison.

In particular, the total energy throughput corresponds to the total energy throughput since the installation of the—in particular, new—high-voltage storage device in the electric vehicle. Typically, the ageing of a high-voltage storage device is greater, the higher the total energy throughput thereof. Potential classes can exemplarily comprise one class having a low total energy throughput, and one class having a high total energy throughput. The class having a low total energy throughput can be associated, for example, with “infrequent driving”, which is more protective of the battery than “frequent driving” with a high total energy throughput.

Thus, in general, the V2X residual service life and, optionally, also the remaining service life of the at least one component can be determined in consideration of a driving behavior and/or a charging behavior of the electric vehicle, or of the user thereof.

In particular, the temperature of the high-voltage storage device signifies a temperature of the high-voltage storage device during charging (i.e. recharging and discharging), either during a charging process at a charging point and/or during a driving operation. It is considered that charging processes at high temperatures are typically associated with a greater loading of a high-voltage storage device than charging processes at lower temperatures. Potential classes can thus exemplarily comprise classes having different value ranges of averaged (charging) temperatures. Determination of the temperature of the high-voltage storage device per unit of time advantageously facilitates correlation with other categories or component parameters which are determined per unit of time, e.g. energy throughput per unit of time at a charging point. According to a further development, it is also possible e.g. that the temperature comprises a corresponding characteristic or a corresponding profile and, for example, is classified in classes which are defined by respective reference characteristics, e.g. by means of a similarity comparison.

With respect to the storage level of the high-voltage storage device, it is considered that a high storage level, in particular with a SoC in excess of 80%, is typically associated with a greater loading of a high-voltage storage device than a lower storage level. Potential classes can thus exemplarily comprise classes having different value ranges of averaged storage levels. Determination of the storage level per unit of time advantageously facilitates correlation with other categories or component parameters which are determined per unit of time. According to a further development, it is also possible e.g. that the storage level comprises a corresponding characteristic or a corresponding profile and, for example, is classified in classes which are defined by respective reference characteristics, e.g. by means of a similarity comparison.

In general, it is also possible that the above-listed battery usage categories are subdivided into multiple battery usage categories, and that thus, for example, the battery usage category “temperature of the high-voltage storage device” is subdivided into the two battery usage categories: “temperature of the high-voltage storage device during charging at a charging point” and “temperature of the high-voltage storage device during a driving operation”, wherein, for the prediction of the at least one associated residual service life variable, one or both of these subcategories can be employed. In the event that both are employed, class divisions can be identical or different. In principle, the number of subcategories is not limited.

According to one configuration, a (“battery”) residual service life variable of the high-voltage storage device corresponds to the state-of-health. The state-of-health, also referred to as SoH, corresponds to the state of ageing of the high-voltage storage device, in comparison with the as-new state thereof. The state-of-health is typically expressed as a percentage of the remaining storage capacity in comparison with its original capacity. The V2X residual service life can be inferred from the state-of-health: it can thus be defined that the end of the V2X residual service life has been reached when the state-of-health has declined to a specific percentage, for example to a 92% SoH.

According to a further development, the remaining service life of the high-voltage storage device is also determined from the state-of-health. It can thus be defined that the end of the remaining service life has been reached when the state-of-health has declined to a specific percentage which is lower than the percentage/threshold value for the achievement of the V2X residual service life, for example to an 85% SoH.

According to a further development, the current (actual) state-of-health is calculated from the model. This state-of-health can exemplarily be displayed to a user for information.

In general, one or more residual service lives or types of residual service life can be determined from the state-of-health, for example a first battery residual service life, wherein V2X operation or the facility for reinjection is limited, for example with respect to a discharge capacity and/or a discharged quantity of energy, and a second battery residual service life, upon the achievement or expiry of which V2X operation is entirely inhibited. The first battery residual service life is thus shorter than the second battery residual service life. However, it is also possible for only a single battery residual service life to be determined, upon the expiry of which V2X operation is inhibited. According to one configuration, the at least one residual service life for V2X operation thus comprises a residual service life wherein a reinjection operation is limited, and/or comprises a residual service life wherein a reinjection operation is inhibited.

According to one configuration, the at least one component comprises at least one battery electronics unit for operating the at least one high-voltage storage device. Hereinafter, component usage categories thereof, without loss of generality, are also designated as part usage categories. This configuration advantageously considers that the service life of a high-voltage storage system is not only limited by the storage device itself, but also by the ageing of the associated electronic component(s).

According to one configuration, the at least one part usage category comprises at least one usage category from the following group:
hours of service of the electronic component (e.g. in hours);
temperature of the electronic component, in particular per unit of time.

The classes with respect to hours of service can be, for example, different value ranges. According to a further development, the component temperature comprises a temperature characteristic or a temperature profile, and can be classified, for example, in temperature classes which are defined by reference characteristics, e.g. by means of a similarity comparison. In particular, the component temperature is only captured during a charging operation of the associated high-voltage storage device. By means of this configuration, it is considered that an operative electronic component undergoes greater ageing than an inoperative electronic component, and that an—in particular operative—electronic component undergoes greater ageing at a higher temperature than at a lower temperature.

According to one configuration, the at least one residual service life variable corresponds to a remaining service life, subject to the deduction of a respectively stipulated time interval (designated hereinafter, without loss of generality, as the “V2X service life margin”). This advantageously enables a reliable, but nevertheless flexible adjustment of the V2X operation of the component considered. According to one variant, the remaining service life corresponds to the duration of service up to the foreseeable end-of-life of the component, and can be indicated, for example, in charging/operating hours or in calendar time. For example, a first V2x residual service life can be determined, at which V2X operation or reinjection operation is restricted, for example with respect to a discharge capacity and/or a discharged quantity of energy, and a second V2X residual service life can be determined, upon the achievement or expiry of which V2X operation is entirely inhibited. The first V2X residual service life is shorter than the second V2X residual service life, as a greater V2X service life margin is applied. However, it is also possible for only a single residual service life to be determined for a component, upon the expiry of which V2X operation or a reinjection operation is inhibited. In general, the predicted residual service life variable can correspond to the remaining service life of the component, from which the V2X residual service life can be exemplarily determined as described above. In principle, this configuration is applicable both to electronic components, by way of components, and to the high-voltage storage device, by way of the component. A circumstance is thus exemplarily included wherein the remaining service life of the high-voltage storage device is not determined by reference to the SoH, but is calculated otherwise.

According to one configuration, depending upon the at least one V2X residual service life, at least one measure is selected for an extension of the remaining service life. This at least one measure can comprise, for example, the driving behavior of the user (e.g. a selection of a driving mode, a customary driving speed, etc.) and/or the charging behavior at a charging point (e.g. a selection of a charging mode, a charging time, etc.), which driving behavior can be varied for the extension of the V2X residual service life of at least one component, and particularly of the remaining service life thereof. In particular, the measure can be employed for the variation of the usage behavior, such that the latter falls within a class of at least one usage category which is more advantageous for the V2X residual service life.

According to one configuration, at least one behavioral instruction corresponding to the at least one measure is output for the attention of a user of the electric vehicle. A user is thus advantageously enabled to optionally schedule or refuse a potential V2X operation of the electric vehicle, and also to anticipate a replacement of the high-voltage storage device and of the associated components. Behavioral instructions can exemplarily include instructions which can be implemented by the user and can result in a prolonged operating time in a V2X operating mode and/or in a prolonged service life, for example an instruction for the reduced employment of fast charging, adoption of a driving mode which conserves the storage device to a greater extent, etc., optionally in combination with an indication of the extent by which the operating time(s) and/or service life (or lives) would be extended as a result. The behavioral instructions can be exemplarily transmitted on the electric vehicle and/or on a user terminal, such as a portable user terminal, e.g. a smartphone or a tablet PC.

According to an additional or alternative further development, at least one behavioral instruction corresponding to the at least one measure is output for the attention of a service provider, such as a fleet operator, an authorized workshop, etc. This development can be advantageously employed, for example, for the initiation of preparatory actions, etc.

According to one further development, status indications of the remaining V2X residual service life (or lives) and, optionally, the remaining service life (or lives) of at least one component, particularly of at least the high-voltage storage device, are output for the attention of the user of the electric vehicle, e.g. a current state-of-health of the high-voltage storage device, the currently remaining V2X residual service life (exemplarily indicated in hours of service), a SoC characteristic over the last 24 or 48 hours, etc.

According to one configuration, at least one measure is automatically implemented in conjunction with a charging process of the electric vehicle at a charging point. This is particularly advantageous if a measure of this type is implemented in a manner which is practically imperceptible to the user. For example, a commencement of a charging process at a charging point can be delayed, in order to enable the execution of the charging process at lower temperatures than those prevailing immediately after a driving operation, or at a time when the ambient temperature is lower, for example at night. According to one further development, permission from a user is sought prior to the implementation of such a measure.

According to one configuration, the at least one category, or classes thereof, and/or models have been set up by reference to a fleet behavior. This achieves the advantage that the set-up of the category, or classes thereof, and/or of models is enabled on the basis of practically relevant and statistically reliable data. A further advantage is that, by the evaluation of fleet behavior, the categories, or classes thereof, and/or models can be continuously updated and improved. In particular, the fleet behavior comprises the usage behavior of the high-voltage storage device and, optionally, of the vehicle component(s) for the operation of the high-voltage storage device, a group or “fleet” of multiple electric vehicles, specifically of a high number of multiple vehicles, which comprise comparable high-voltage storage devices and. optionally, vehicle components. The fleet can comprise, for example, electric vehicles produced by the same manufacturer.

According to a further development, the V2X residual service life of at least one component, in particular of the high-voltage storage device, is routinely determined, in particular together with the remaining service life thereof. This achieves the advantage that a dynamic updating of the V2X residual service life (or lives) is enabled.

The object is also fulfilled by a prediction system, which comprises at least one electric vehicle and a data processing entity which is external thereto, wherein the prediction system is designed to execute the above-described method. The prediction system can be configured in an analogous manner to the method, and vice versa, and assumes the same advantages.

The external data processing entity is digitally coupled to the electric vehicle and, advantageously, to multiple electric vehicles of an entire vehicle fleet. The external data processing entity can be, for example, a backend of the electric vehicle manufacturer. In particular, data with respect to the usage behavior of the at least one component of the high-voltage storage system can be captured by the electric vehicle and relayed to the external data processing entity, in particular both during a driving operation and during a charging operation of the electric vehicle. The external data processing entity can employ these data for the categorization of usage behavior, for the identification of a component model which is appropriate to this categorization, and for determining the remaining residual service life (or lives) for V2X operation and, optionally, the remaining service life (or lives). These variables thus determined can be transmitted to the electric vehicle and/or to a user terminal, such as a portable user terminal, e.g. a smartphone. Moreover, the external data processing entity can optionally select the above-described measures and execute the set-up of instructions and the transmission thereof to the electric vehicle and/or to a user terminal.

According to one configuration, the prediction system additionally comprises a property, which incorporates at least one charging point to which the electric vehicle is connected for a charging operation. The property can comprise an energy meter, which is designed to measure the charging current flowing from the charging point to the electric vehicle, and a discharging current flowing from the electric vehicle to the charging point and, typically, the associated voltage thereof. These data can be captured by the property and relayed to the external data processing entity.

However, the functions of the prediction system can be entirely or partially assumed by the electric vehicle, particularly in conjunction with, or in a distributed arrangement with the prediction system. In consequence, the object is also fulfilled by an electric vehicle which is designed to entirely or partially execute the above-described method. The electric vehicle can be configured in an analogous manner to the method and/or to the prediction system, and vice versa, and assumes the same advantages.

The above-described properties, features and advantages of the present invention, and the manner in which they are achieved, are further clarified and explained in conjunction with the following schematic description of one exemplary embodiment, which is described in greater detail in conjunction with the drawings.

### BRIEF DESCRIPTION OF THE DRAWINGS

FIG. 1 shows a system having an electric vehicle, a property and an external data processing entity; and

FIG. 2 shows a potential sequence for executing the method by means of the external data processing facility.

### DETAILED DESCRIPTION OF THE DRAWINGS

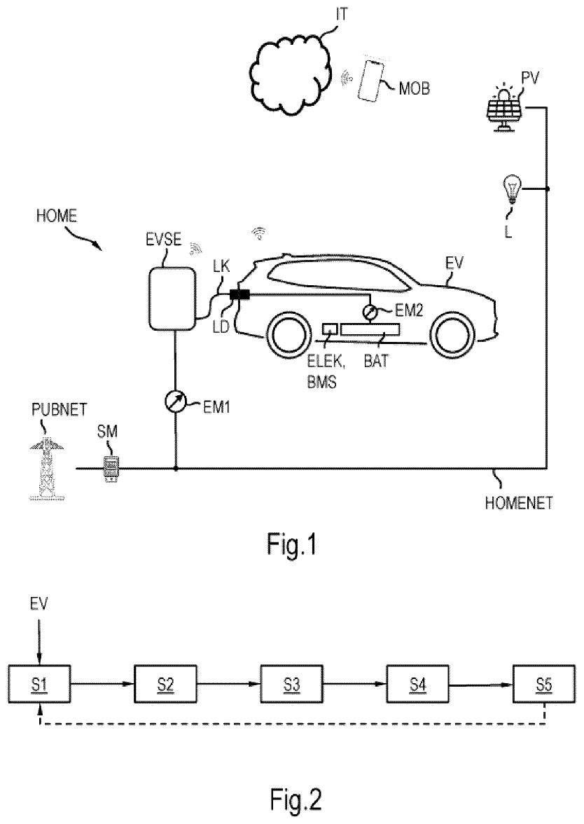

FIG. 1 shows a system comprising an electric vehicle EV which is enabled for bidirectional charging, having at least one high-voltage storage device in the form of a drive battery BAT, a property in the form of a single-family residence HOME, and an external data processing entity (external IT system) IT, which can correspond e.g. to a backend of the manufacturer of the electric vehicle EV.

The single-family residence HOME comprises a typically AC-operated energy grid (“home energy grid”) HOMENET, which is connected to a public electricity supply grid PUBNET via a grid connection point. An electricity meter is located at the grid connection point, in the present exemplary case in the form of a “smart meter” SM. According to a further development, down-circuit of the grid connection point, a further (unrepresented) energy metering device can be integrated in the home energy grid HOMENET, which device is controlled by the user of the single-family residence HOME.

Domestic loads L such as household appliances, lamps, multimedia devices, heat-pumps, air-conditioning systems etc. are connected to the home energy grid HOMENET. Moreover, at least one autonomous electricity generating facility, such as the photovoltaic installation PV represented and, optionally, at least one (unrepresented) stationary buffer storage device can be connected to the home energy grid HOMENET. The single-family residence HOME can moreover be provided with an (unrepresented) home energy management system, which can be particularly advantageous for controlling an energy flux in the home energy grid HOMENET and between the home energy grid HOMENET and the public electricity supply grid PUBNET, if possible, for example for the achievement of a stipulated target, such as a cost saving or a reduction of an ecological footprint. This control is particularly effectively enabled in the event that the home energy grid HOMENET is provided with an electrical buffer storage device. This buffer storage device can not only be the stationary buffer storage device, but can also be the electric vehicle EV, in the event of the connection thereof via a charging point which charges bidirectionally, such as the wallbox EVSE represented.

The wallbox EVSE is provided with a rectifier, which, for charging the drive battery BAT, converts an alternating current of the home energy grid HOMENET into a direct current which flows to a charging socket LD of the electric vehicle EV. In particular, the charging current flows from the wallbox EVSE through a charging cable LK to the charging socket LD, and thereafter to the drive battery BAT. The wallbox EVSE is moreover provided with an inverter, which, for discharging the drive battery BAT, converts a direct current which is reinjected from the electric vehicle EV via the charging cable LK into an alternating current, and injects it into the home energy grid HOMENET. The currents flowing through the wallbox EVSE can be exemplarily metered by means of an energy metering device EM1. Moreover, the charging current flowing into and out of the drive battery BAT can be metered by means of an energy metering device EM2 which is installed in the electric vehicle. The energy metering devices EM1 and EM2 can also be designed for measuring the electric voltage. Alternatively, the rectifier can be installed in the electric vehicle EV, in which case the charging socket LD is then an AC socket.

The operation of the drive battery BAT, including a charging operation, i.e. recharging or discharging, is controlled by battery electronics ELEK, in which a battery management system BMS can also be implemented. The battery electronics ELEK are thus additionally switched-in in conjunction with each operation of the drive battery BAT.

In particular, by means of the battery management system BMS or by means of an (unrepresented) home energy management system, a charging plan for charging the electric vehicle EV can be generated, and, depending on marginal conditions in force, such as electricity tariffs, a proportion of green energy, etc., and in accordance with targets pursued, can also provide for energy discharged from the drive battery BAT to be reinjected into the public electricity supply grid PUBNET (V2G) application), or to be used for charging the stationary buffer storage device, or for operating domestic loads L (V2H application).

In the present case, the electric vehicle EV is designed, e.g. by means of the battery management system BMS, in particular at regular intervals, to determine various data with respect to the drive battery BAT and the battery electronics ELEK, and to execute the transmission thereof to the external data processing entity IT, particularly including component parameters which are employable for the purposes of categorization. Data transmitted with respect to the drive battery BAT can exemplarily include the following: an energy throughput of the drive battery BAT (in total and/or per unit of time, e.g. measured as a capacity), optionally distinguished according to recharging and discharging, a temperature of the drive battery BAT, a storage device storage level, a number of charging (i.e. recharging/discharging) cycles, etc. Data transmitted with respect to the battery electronics ELEK can exemplarily comprise the following: hours of service, temperature, etc. According to a further development, the data with respect to the drive battery BAT and the battery electronics ELEK represent only subsets of all data transmitted. Further data can exemplarily include a mileage of the electric vehicle EV (e.g. expressed in km), a speed, an external temperature, etc. The data processing entity IT can save the data thus transmitted and generate, for example, corresponding temporal characteristics or curves therefrom, for example a storage level characteristic, at least one temperature characteristic, etc.

In particular, the data processing entity IT is designed, on the basis of the data thus transmitted and of models, etc., to execute the present method. Thus, for example, the data processing entity IT can determine the state-of-health of the drive battery BAT by category-based modelling, and determine the remaining service life for V2X operation therefrom. The data processing entity IT can also be designed to determine the remaining service life of the battery electronics ELEK, and the residual service life thereof for V2X operation. Data thus determined, including, for example, the (SoC; t) characteristic, the state-of-health and service life (or lives), can be transmitted to the electric vehicle EV, or to a terminal, in particular to a portable user terminal, such as a smartphone MOB.

FIG. 2 shows a potential sequence for the execution of the method by means of the external data processing facility IT. The data processing facility IT has access to category-specific models of the drive battery BAT and of the battery electronics ELEK. In particular, it is designed for updating these models by reference to data received from a fleet of comparable electric vehicles.

In a step S1, the data processing facility IT receives, in particular at regular intervals, various component parameters or values thereof from the electric vehicle EV, which describe at least, or inter alia, the usage behavior of the drive battery BAT and of the battery electronics ELEK, and optionally general vehicle parameters, such as driving data, etc. The data processing facility IT can save the data thus received, in order to generate or maintain temporal characteristics therefrom.

In a step S2, values and/or characteristics thus received for the component parameters are categorized in corresponding categories from a group of battery usage categories and/or part usage categories, e.g. by classification.

In a step S3, the data processing facility IT determines or selects the most appropriate models of the drive battery BAT and of the battery electronics ELEK for the categorization executed in step S2.

In a step S4, by reference to the (present and historic actual) data transmitted by the electric vehicle—which data reflect the usage behavior of the drive battery BAT and of the battery electronics ELEK—and by reference to the respectively identified models, the respective residual service life variables are predicted, for example, the state-of-health of the drive battery BAT and the remaining service life of the battery electronics ELEK are calculated.

In a step S5, by reference to the at least one predicted residual service life variable of the drive battery BAT and of the battery electronics ELEK, at least one residual service life for the V2X operation of these components BAT, ELEK is determined, e.g. the V2X residual service life of the drive battery BAT is determined from the state-of-health, the V2X residual service life of the battery electronics ELEK is determined from the predicted remaining service life, etc.

In a step S6, some or all of the data transmitted by the electric vehicle EV, and/or some or all of the variables calculated in a model-based manner, in particular V2X residual service lives and remaining service lives, can be transmitted to the smartphone MOB, or similar, and can be displayed thereon as required, optionally in combination with instructions for the extension of the V2X residual service lives and remaining service lives.

For example, the following can be displayed on the smartphone MOB:
the current storage level, e.g. expressed numerically (for example “81%”) and/or in the form of a bar chart, e.g. in battery form;
a temporal characteristic of the storage level over a specific preceding time period, e.g. 24 hours, for example in the form of a chart;
the present state-of-health, e.g. expressed numerically (for example “96%”);
a temporal characteristic of the state-of-health over a specific preceding time period, e.g. plotted against the vehicle age, for example in the form of a chart;
the V2X residual service life of the battery BAT, e.g. the remaining operating time or duration thereof, or expressed in the form of “recharging and discharging”/“reinjection: all OK”, “recharging only”, or similar;
instructions for charging at a charging point, for example “reduce fast charging to preserve SoHT” or “commence recharging at night only”, etc.;
instructions regarding driving behavior, for example “‘ECO Pro’ driving mode will extend your SoH by 3 years”, etc.

This display can be executed by means of an application program or “app”.

In particular, execution of the method can be repeated at regular intervals, in order to enable the updating of results generated therefrom, such as the V2X residual service life or lives, as indicated by the dashed arrowed line.

In the case of a new electric vehicle EV, a starting usage behavior can initially be assumed, which is then typically altered by the actual usage behavior.

Naturally, the present invention is not limited to the exemplary embodiment represented.

In general, the term “a”, “an” etc. can be understood to represent a singularity or a plurality, for example in the sense of “at least one” or “one or more”, etc., unless this is explicitly excluded, e.g. by the expression “exactly one”, etc.

A numerical value can also comprise the exact number indicated, or can incorporate a customary tolerance margin, unless this is explicitly excluded.

### LIST OF REFERENCE SYMBOLS

BAT drive battery
ELEK battery electronics
BMS battery management system
EMi ith energy metering device
EV electric vehicle
EVSE wallbox
HOME single-family residence
HOMENET energy grid of single-family residence
IT external data processing facility
L load
LD charging socket
LK charging cable
MOB user terminal
PUBNET public electricity supply grid
PV photovoltaic installation
SM smart meter
S1-S5 method steps

1-12. (canceled).

13. A method for predicting at least one residual service life of at least one component of a high-voltage storage system which is installed in an electric vehicle, which is designed for bidirectional charging, for V2X operation, the method comprising steps of:
categorizing the at least one component of the high-voltage storage system, by reference to the usage behavior thereof, in at least one respective category of a group of component usage categories;
selecting, by reference to the categorization, a category-specific model for the component;
predicting, by reference to the usage behavior and to the selected model of the at least one component, at least one associated residual service life variable; and
determining, by reference to the at least one predicted residual service life variable, at least one residual service life for the V2X operation of the at least one component.

14. The method according to claim 13, wherein the at least one component comprises at least one of:
at least one high-voltage storage device having at least one battery usage category; or
at least one electronic component for operating the at least one high-voltage storage device, having at least one part usage category.

15. The method according to claim 14, wherein:
the at least one component comprises at least one high-voltage storage device: and
the at least one battery usage category for predicting the at least one residual service life variable of the high-voltage storage device comprises at least two usage categories from a group of battery usage categories comprising at least two of the following usage categories:
energy throughput per unit of time at a charging point;
a number of charging cycles per unit of time or per charging process at a charging point;
energy throughput per unit of time during a driving operation;
number of discharge cycles during a driving operation;
total energy throughput;
temperature of the high-voltage storage device; or
storage level of the high-voltage storage device.

16. The method according to claim 14, wherein a residual service life variable of the high-voltage storage device corresponds to the state-of-health.

17. The method according to claim 13, wherein:
the at least one component comprises at least one electronic component; and
at least one part usage category for predicting the at least one associated service life variable comprises at least one usage category from the following group:
hours of service of the electronic component; or
temperature of the electronic component.

18. The method according to claim 14, wherein:
the at least one residual service life variable for V2X operation corresponds to a remaining service life of the component; and
the residual service life is calculated therefrom, subject to the deduction of a respectively stipulated V2X service life margin.

19. The method according to claim 14, wherein the at least one residual service life for V2X operation comprises at least one of:
a residual service life, upon the expiry of which a reinjection operation is restricted; or
a residual service life, upon the expiry of which a reinjection operation is inhibited.

20. The method according to claim 13, wherein, depending upon the at least one residual service life for V2X operation, at least one measure is selected for an extension of the remaining service life.

21. The method according to claim 20, wherein at least one behavioral instruction corresponding to the at least one measure is output for the attention of a user, operator or manufacturer of the electric vehicle.

22. The method according to claim 20, wherein at least one measure is automatically implemented in conjunction with a charging process of the electric vehicle at a charging point.

23. The method according to claim 13, wherein at least one of the at least one category or the model is, or has been set up, by reference to a fleet behavior.

24. A prediction system comprising:
at least one electric vehicle; and
a data processing entity which is external thereto,
wherein the prediction system is configured to execute the method of claim 13.
